(19) United States
(12) Patent Application Publication
(10) Pub. No.: US 2012/0139067 A1
(43) Pub. Date: Jun. 7, 2012

(54) PRESSURE SENSOR AND METHOD OF PACKAGING SAME

(75) Inventors: WAI YEW LO, Petaling Jaya (MY); Lan Chu Tan, Shah Alam (MY); Jinzhong Yao, Tianjin (CN)

(73) Assignee: FREESCALE SEMICONDUCTOR, INC, Austin, TX (US)

(21) Appl. No.: 13/246,877

(22) Filed: Sep. 28, 2011

(30) Foreign Application Priority Data
Dec. 6, 2010 (CN) 201010601547.9

(51) Int. Cl. H01L 21/50; H01L 29/84

(52) U.S. Cl. 257/417; 438/51; 257/E21.499; 257/E29.324

(57) ABSTRACT

A method of packaging a pressure sensor die that does not use pre-molded lead frames. Instead a lead frame array is attached to a tape and a non-conductive material is deposited on the lead frames. The non-conductive material is cured and the tape is removed. Pressure sensor dies then are attached to respective die pads of the lead frames and electrically connected to lead frame leads with bond wires. A gel is dispensed onto a top surface of the pressure sensor dies and then a lid is attached to each of the lead frames to cover the pressure sensor dies. The lead frames are singulated to form individual pressure sensor packages.

### BACKGROUND OF THE INVENTION

The present invention relates generally to pressure sensor packaging, and more particularly to a method of assembling quad flat no-lead (QFN) pressure sensor packages.

Portable electronic devices are starting to integrate sensors into handheld and desktop electronics with requirements of low power and a small form factor. Key markets are in the cellular, mobile electronics and desktop arenas. For example, pressure sensors are being used in small form factors to measure barometric pressure as a means to analyze surroundings. This is occurring in portable devices for weather measurement or in control systems for electronics dependent on operating pressures. Pressure sensors may be packaged with a microcontroller to attain compensated pressure values using the raw data provided by the pressure sensor.

Pressure sensors and pressure sensor packages come in a variety of sizes and configurations. The pressure sensor die typically has a thin differential pressure-sensing membrane that is susceptible to mechanical damage during handling and packaging. For this reason, the sensor die typically is mounted in a pre-molded package and then sealed in the package using a separate cover/lid.

One way of packaging the pressure sensor die is mounting the die to a premolded lead frame and encapsulating the package with a mold compound. However, dies such as piezo resistive transducer (PRT), parameterized layout cell (Pcell) and Gyro do not allow full encapsulation because that would impede their functionality. As a result, the premolded lead frame requires a metal lid or cap be placed over the die to protect it from the outside environment. However, premolded lead frames are relatively expensive, which increases the overall cost of the packaged device.

Accordingly, it would be advantageous to be able to efficiently package pressure sensor dies in which the risk of environmental damage to the pressure sensor die is substantially reduced or eliminated while reducing the overall packaging costs.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1A is a cross-sectional view of a pressure sensor package in accordance with one embodiment of the present invention;

FIG. 1B is a top view of a quad flat no-lead (QFN) pressure sensor package in accordance with one embodiment of the present invention;

FIG. 2 is a side cross-sectional view illustrating a plurality of lead frames with an adhesive tape attached to the lead frames;

FIGS. 3, 4 and 5 illustrate steps of depositing a non-conductive material on the lead frames of FIG. 2;

FIGS. 6, 7 and 8 illustrate steps of attaching pressure sensor dies to the corresponding lead frames;

FIG. 9 illustrates a step of dispensing a gel on each of the pressure sensor dies;

FIG. 10 illustrates a step of curing the gel dispensed on the pressure sensor dies;

FIGS. 11 and 12 illustrate steps of attaching lids to respective lead frames to form an array of packaged pressure sensor dies; and

FIG. 13 illustrates a step of separating the packaged pressure sensor dies in the array into individual packaged pressure sensor dies.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention provides a method of packaging a pressure sensor die. The method includes providing a plurality of lead frames. Each of the plurality of lead frames includes a die pad and a plurality of lead fingers. A tape is attached to a first side of the plurality of lead frames and a non-conductive material is deposited on a second side of the lead frames. The non-conductive material is cured and the tape is removed to attach pressure sensor dies to respective die pads of the lead frames with a die attach adhesive. The die attach adhesive is then cured and bond pads of the respective pressure sensor dies are electrically connected to the lead fingers of the lead frames with wires using a wire bonding process. A gel is dispensed onto a top surface of each of the pressure sensor dies. The gel is cured and a lid is attached to each of the lead frames with a lid attach adhesive such that the lids cover the pressure sensor dies. The lid attach adhesive is cured and the plurality of lead frames are singulated to form individual pressure sensor packages.

In another embodiment, the present invention is a packaged pressure sensor die formed in accordance with the above-described method.

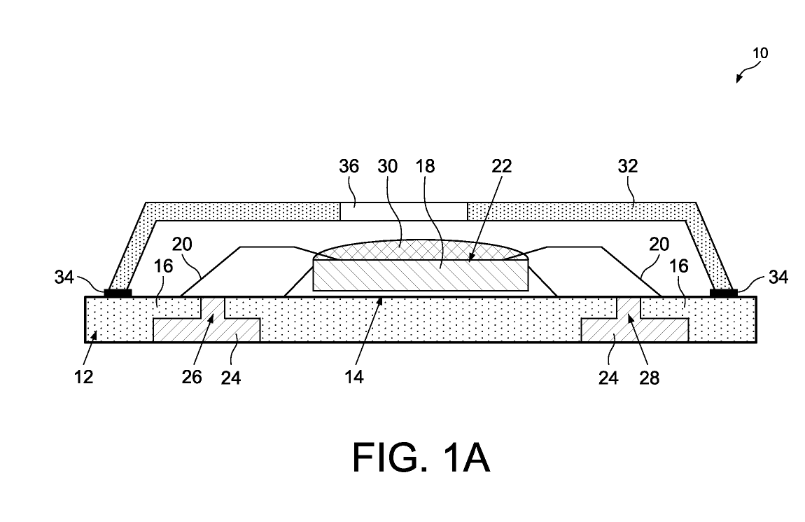

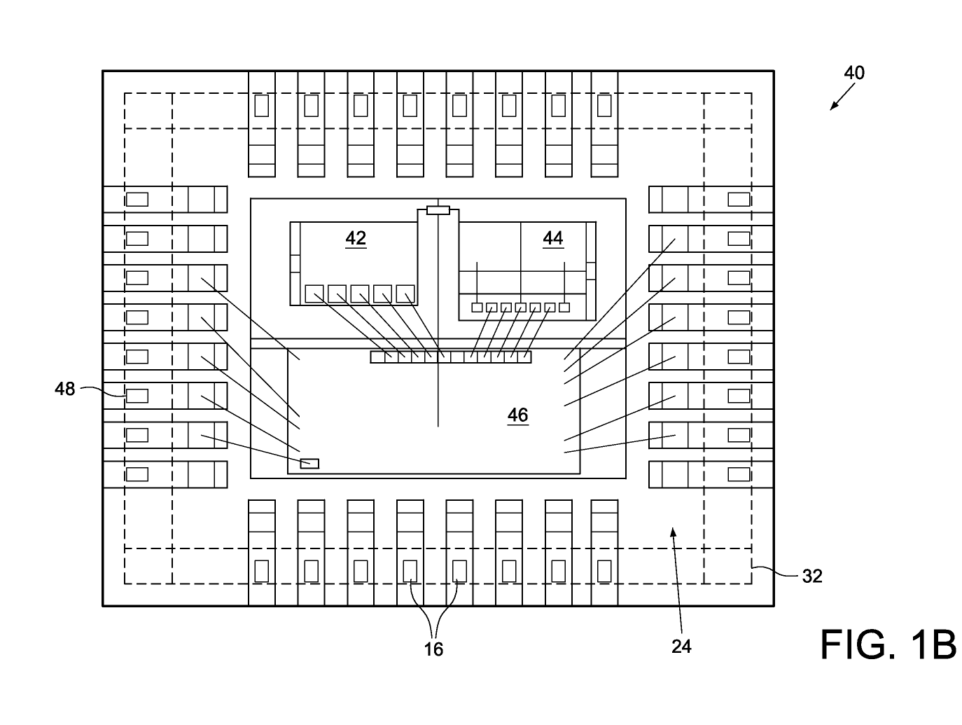

Referring now to FIG. 1A, a cross-sectional view of a packaged pressure sensor die or pressure sensor die package 10 is shown. The pressure sensor die package 10 includes a lead frame 12 with a die pad 14 and lead fingers 16. The lead frame 12 may be formed of copper, an alloy of copper, a copper plated iron/nickel alloy, plated aluminum, or the like.

A pressure sensor die 18 is attached and electrically coupled to the lead frame 12. In this exemplary embodiment of the invention, the pressure sensor die 18 includes a piezo resistive transducer (PRT) die. The pressure sensor die 18 may be attached to the lead frame 12 using a die attach adhesive. The pressure sensor die 18 and the lead frame 12 are well known components of pressure sensors and thus detailed descriptions thereof are not necessary for a complete understanding of the present invention.

In this embodiment of the invention, the pressure sensor die 18 is electrically coupled to the lead fingers 18 of the lead frame 12 with bond wires 20. The bond wires 20 are bonded to pads on an active surface 22 of the pressure sensor die 18 and to the lead fingers 16 of the lead frame 12, using a well known wire bonding process and known wire bonding equipment.

Another way of electrically connecting the pressure sensor die 18 to the lead fingers 16 of the lead frame 12 is to connect bond pads of the pressure sensor die 18 to the lead fingers 16 with flip-chip bumps (not shown) attached to an underside of the pressure sensor die 18. The flip-chip bumps may include solder bumps, gold balls, molded studs, or combinations thereof, as is known in the art.

The pressure sensor die package 10 includes a non-conductive material 24 such as a non-conductive adhesive or a solder mask disposed within gaps 26 and 28 between the die pad 14 and the lead fingers 16. A gel 30 such as a silicon-based gel is disposed on a top surface of the pressure sensor die 18 to cover the bond pads and the electrical connections (wire bonds) of the pressure sensor die 18 as well as the die 18 itself.

The packaged pressure sensor die 10 includes a lid 32 that covers the pressure sensor die 18, the die pad 14, the gaps 26, 28, and the bond wires 20. The lid 32 may include a molded, footed metal lid, as is known in the art. In this exemplary embodiment of the invention, the lid 32 is attached to the lead frame 12 with a lid attach adhesive 34 such as a non-conductive epoxy. However, other attachment mechanisms may be used. The lid 32 includes a vent hole 36 on a top surface thereof. It should be noted that the non-conductive material 24 and the lid attach adhesive 34 substantially preventingress of moisture into the pressure sensor die 18 by interlocking the lead frame 12 and the metal lid 32 at the sides and bottom of the packaged pressure sensor die 10. The example configuration of the packaged pressure sensor die 10 of FIG. 1A may be used in a flat no-lead type package.

Referring now to FIG. 1B, a top view of a quad flat no-lead (QFN) sensor package 40 is shown. In this embodiment, the package 40 includes three dies, specifically a parameterized layout cell (PCELL) 42, a sensor chip (GCELL) 44 and a microcontroller (MCU) 46. An outline of the lid 32 is shown with dashed lines. The non-conductive material 24 and the lid 32 surround the dies 42, 44, 46 and act to substantially preventingress of moisture into the package 40 by interlocking the package 40 at the sides and bottom. The package 40 has exposed leads 48 on all four sides thereof.

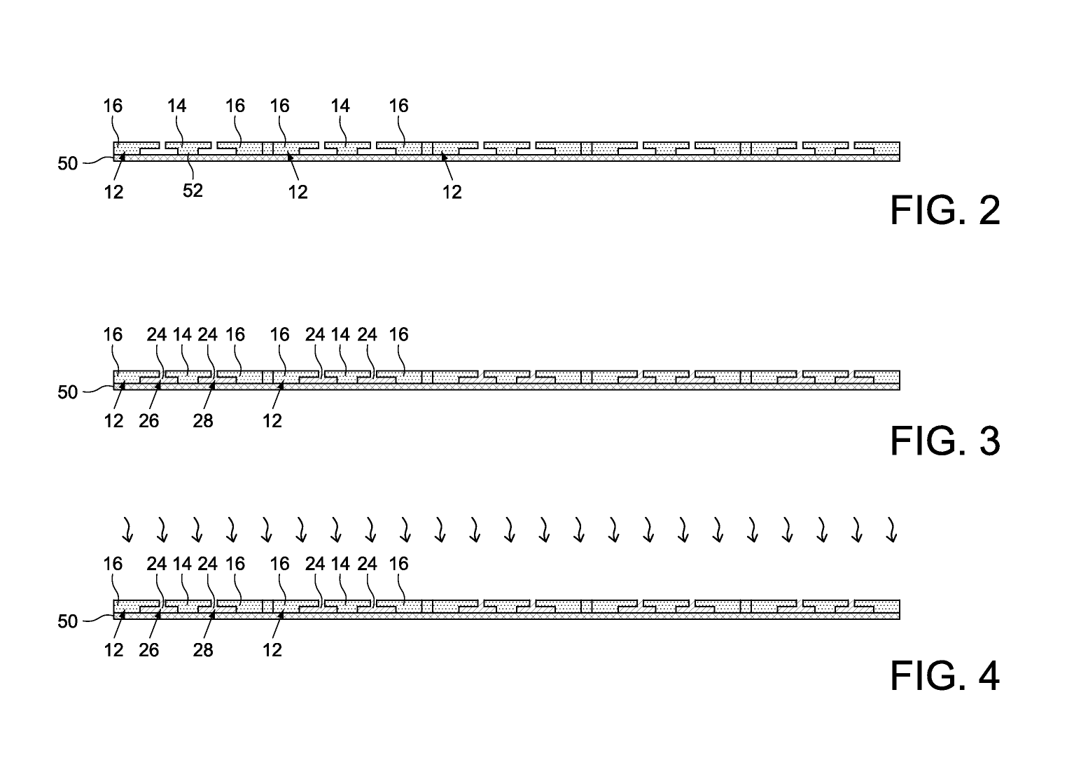

Although the individual elements of the packages 10 and 40 may be well known, the method of assembly of such elements in the conventional packages is cumbersome and as previously discussed requires premolded lead frames. However, the inventors have discovered a novel method of forming the packaged pressure sensor die 10 that will be described with reference to FIGS. 2-13. Instead of using a premolded lead frame, a simple printing technique is used to apply a non-conductive material to a bare (non-premolded) lead frame, which, along with the lid, seals the die(s) within the package.

FIG. 2 is a side cross-sectional view showing a plurality of lead frames 12 with an adhesive tape 50 attached to a first or bottom side 52 of the lead frames 12. As illustrated, each lead frame 12 includes a die pad 14 and lead fingers 16. The plurality of lead frames 12 may be available in the form of a single strip with adjacent individual segmented frames or an array.

FIG. 3 is an illustration of a step of depositing a non-conductive material 24 such as a solder mask on a second side 54 of the lead frames 12. In one embodiment of the invention, the non-conductive material 24 is deposited on the lead frames with a screen printing process using known screen printing equipment. The deposition of the non-conductive material 24 is performed such that the non-conductive material 24 substantially fills the gaps 26 and 28 between the die pad 14 and the lead fingers 16 of each lead frame 12.

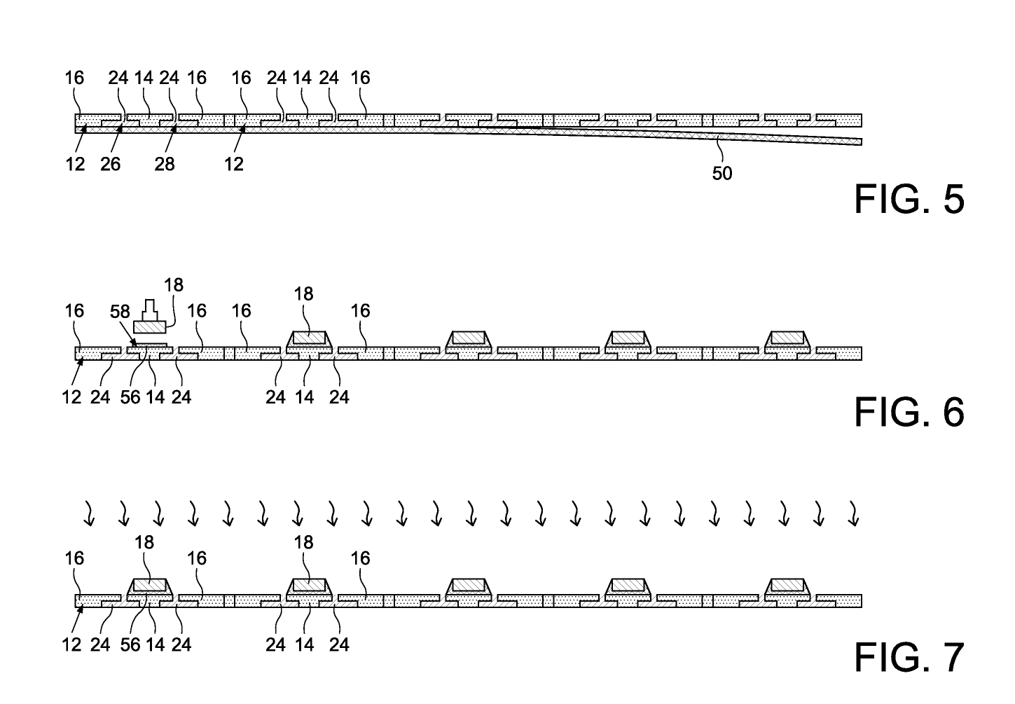

The deposited non-conductive material 24 is subsequently cured in a conventional oven followed by removal of the tape 50 from the lead frames 12, as shown in FIGS. 4 and 5.

FIG. 6 is an illustration of a step of attaching pressure sensor dies 18 to the lead frames 12. The pressure sensor dies 18 are attached to respective die pads 14 of the lead frames 12 with a die attach adhesive 56 such as die-bonding epoxy. The die attach adhesive 56 is dispensed on a second or top surface 58 of the lead frames 12 using a known dispensing device and the pressure sensor dies 18 are placed on the die attach adhesive 56 to attach the dies 18 to the respective die pads 14. The die attach adhesive 56 is subsequently cured in an oven to harden the die attach adhesive, as shown in FIG. 7.

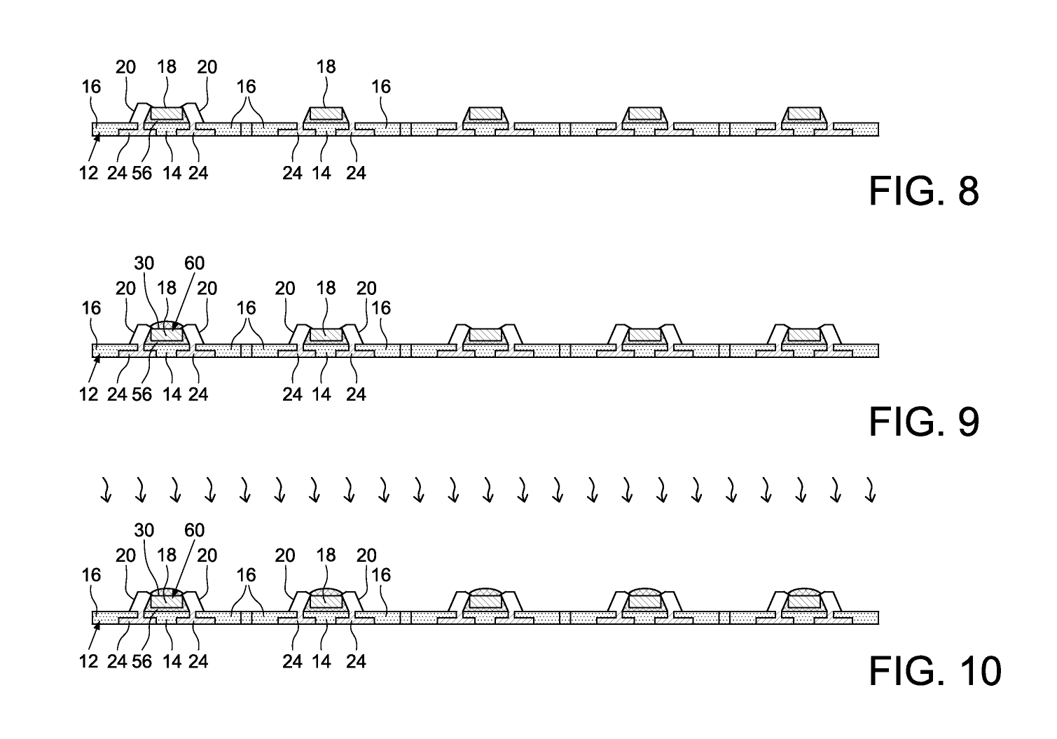

FIG. 8 shows the step of electrically connecting the pressure sensor dies 18 to respective lead frames 12. In this exemplary embodiment of the invention, bond pads of the pressure sensor dies 18 are electrically connected to the lead fingers 16 of the lead frames with the bond wires 20 using a well known wire bonding process and known wire bonding equipment. Another way of connecting the pressure sensor dies 18 to the lead frames 12 is through flip-chip bumps (not shown) attached to an underside of the pressure sensor die 18. The flip-chip bumps may include solder bumps, gold balls, molded studs, or combinations thereof. The bumps may be formed or placed on the pressure sensor die 18 using known techniques such as evaporation, electroplating, printing, jetting, stud bumping and direct placement. For flip-chip, each pressure sensor die 18 is flipped and the bumps are aligned with contact pads (not shown) of the lead fingers 16.

FIG. 9 shows the step of dispensing a gel 30 on a top surface 60 of each of the pressure sensor dies 18. The gel 30, which may be a silicon-based gel, is dispensed onto the top surfaces 60 of the pressure sensor dies 18 to cover the die bond pads of the pressure sensor dies 18. The gel 30 may be dispensed with a nozzle of a conventional dispensing machine, as is known in the art. Subsequently, the gel 30 is cured in an oven, as shown in FIG. 10.

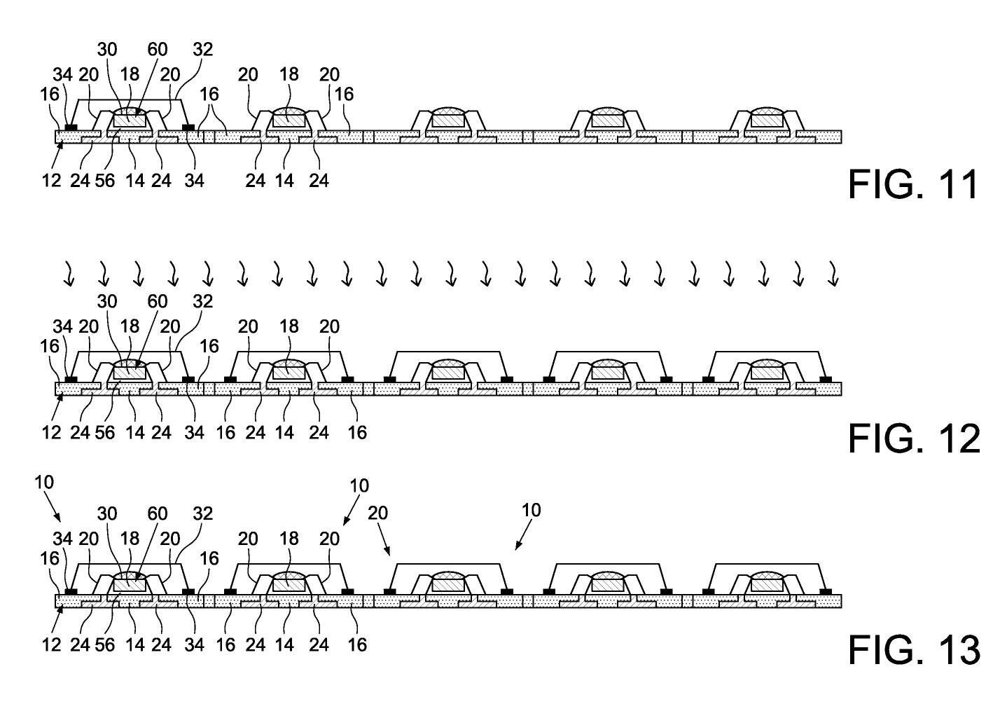

FIG. 11 is a side cross-sectional view showing a lid 32 attached to the lead frame 12. In this exemplary embodiment of the invention, the lid 32 comprises a footed metal lid attached to the lead frame using a lid attach adhesive 34. The lid attach adhesive 34 is subsequently cured in a conventional oven, as illustrated in FIG. 12 to form an array of packaged pressure sensor dies.

FIG. 13 shows the array of packaged dies 10 being separated from each other by a singulation process. Singulation processes are well known and may include cutting with a saw or a laser. As illustrated, the plurality of lead frames 12 is separated from each other to form the individual sensor packages 10.

The present invention, as described above, allows for packaging a pressure sensor die without requiring premolded lead frames to package the die. A simple deposition technique such as screen printing is employed to apply a layer of a non-conductive material to interlock the leads and lead frames. The pressure sensor dies are attached to the respective lead frames with a die attach adhesive, electrically coupled to the lead fingers, and a gel is disposed on the pressure sensor dies to cover the bond pads of the pressure sensor dies. Subsequently, the lid is attached to the package using a footed lid that can be attached to the lead fingers, instead of having to use a lid that is attached to a mold wall. Thus, a mold wall also is not required.

Thus, the present invention provides a method of packaging a pressure sensor die such as QFN packages with a lower package profile that does not require a premolded lead frame for facilitating lid attachment thereby reducing manufacturing costs for such packages. The pressure sensor die packaged using the process described above is protected from air moisture as the lead frame and the metal lid are interlocked at the sides and bottom of the package.

By now it should be appreciated that there has been provided an improved packaged pressure sensor die and a method of forming the packaged pressure sensor die. Circuit details are not disclosed because knowledge thereof is not required for a complete understanding of the invention. Although the invention has been described using relative terms such as “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A method of packaging a pressure sensor die, comprising the steps of:
providing a plurality of lead frames, each of the plurality of lead frames having a die pad and a plurality of lead fingers;
attaching a tape to a first side of the plurality of lead frames;
depositing a non-conductive material on a second side of the lead frames, wherein the non-conductive material substantially fills gaps between the die pad and the lead fingers of each lead frame;
attaching pressure sensor dies to respective die pads of the lead frames with a die attach adhesive and curing the die attach adhesive;
electrically connecting bond pads of the respective pressure sensor dies to the lead fingers of the lead frames;
dispensing a gel onto a top surface of each of the pressure sensor dies; and
attaching a lid to each of the lead frames with a lid attach adhesive, wherein the lids cover the pressure sensor dies, the gel and the electrical connections between the dies and the lead fingers.

2. The method of packaging a pressure sensor die of claim 1, further comprising removing the tape after depositing the non-conductive material.

3. The method of packaging a pressure sensor die of claim 2, further comprising curing the non-conductive material prior to removing the tape.

4. The method of packaging a pressure sensor die of claim 1, wherein the non-conductive material comprises a solder material.

5. The method of packaging a pressure sensor die of claim 4, wherein the non-conductive material is deposited on the lead frame with a screen printing process.

6. The method of packaging a pressure sensor die of claim 1, wherein attaching the lid comprises attaching the lid to the lead fingers.

7. The method of packaging a pressure sensor die of claim 6, further comprising curing the lid attach adhesive.

8. The method of packaging a pressure sensor die of claim 1, further comprising the step of singulating the plurality of lead frames to form individual pressure sensor packages.

9. The method of packaging a pressure sensor die of claim 1, wherein the electrically connecting step comprises connecting the bond pads of the respective pressure sensor dies to the lead fingers of the lead frames with wires using a wire bonding process.

10. The method of packaging a pressure sensor die of claim 1, wherein the electrically connecting step comprises directly connecting the bond pads of the pressure sensor dies to the lead fingers with flip-chip bumps.

11. The method of packaging a pressure sensor die of claim 1, further comprising the step of curing the gel before attaching the lid.

12. A packaged pressure sensor die, comprising:
a lead frame with a die pad and lead fingers;
a pressure sensor die attached and electrically coupled to the lead frame;
a non-conductive material deposited within gaps between the die pad and the lead fingers; and
a lid covering the pressure sensor die and the lead frame.

13. The packaged pressure sensor die of claim 12, wherein the pressure sensor die comprises a piezo resistive transducer (PRT) die.

14. The packaged pressure sensor die of claim 12, wherein the non-conductive material comprises a solder material.

15. The packaged pressure sensor die of claim 12, wherein the pressure sensor die is electrically coupled to the lead frame with bond wires.

16. The packaged pressure sensor die of claim 15, further comprising a gel disposed on a top surface of the pressure sensor die to cover the bond pads of the die.

17. The packaged pressure sensor die of claim 16, wherein the gel comprises silicon-based gel.

18. The packaged pressure sensor die of claim 12, wherein the pressure sensor die is electrically coupled to the lead frame via a plurality of electrically conductive bumps.

19. The packaged pressure sensor die of claim 12, wherein the packaged pressure sensor die comprises a quad flat no-leads (QFN) package.

20. A method of packaging a pressure sensor die, comprising the steps of:
providing a plurality of lead frames, each of the plurality of lead frames having a die pad and a plurality of lead fingers;
attaching a tape to a first side of the plurality of lead frames;
screen printing a non-conductive material on a second side of the lead frames such that the non-conductive material substantially fills gaps between the die pad and the lead fingers of each lead frame;
curing the non-conductive material and removing the tape;
attaching pressure sensor dies to respective die pads of the lead frames with a die attach adhesive and curing the die attach adhesive;
electrically connecting bond pads of the respective pressure sensor dies to the lead fingers of the lead frames with wires using a wire bonding process;
dispensing a gel onto a top surface of each of the pressure sensor dies;
curing the gel;
attaching a lid to each of the lead frames with a lid attach adhesive, wherein the lids cover the pressure sensor dies;
curing the lid attach adhesive; and
singulating the plurality of lead frames to form individual pressure sensor packages.
